(19) United States
(12) Patent Application Publication
(10) Pub. No.: US 2026/0283017 A1
(43) Pub. Date: Sep. 17, 2026

(54) METHOD OF FORMING A CHIPLET DEVICE PROTOTYPE

(71) Applicant: Microchip Technology Inc., Chandler, AZ (US)

(72) Inventor: Julius Andrew Kovats, Manitou Springs, CO (US)

(73) Assignee: Microchip Technology Inc., Chandler, AZ (US)

(21) Appl. No.: 19/262,186

(22) Filed: Jul. 8, 2025

Related U.S. Application Data
(60) Provisional application No. 63/772,815, filed on Mar. 17, 2025.

(51) Int. Cl. H01L 23/00; H01L 21/66; H01L 21/78; H01L 25/00; H01L 25/065

(52) U.S. Cl. CPC H10W 90/00; H10P 54/00; H10P 74/207; H10W 70/05; H10W 70/654; H10W 72/0198

(57) ABSTRACT

A method includes (a) forming a first device including first bond pads, and first function circuitry located in a partial footprint of the first device, (b) forming a second device including second bond pads, and second function circuitry located in a partial footprint of the second device, (c) forming first relocated bond pads within the partial footprint of the first IC device, and forming redistribution layer (RDL) structures to connect respective first bond pads with respective first relocated bond pads, (d) forming second relocated bond pads within the partial footprint of the second IC device, and forming RDL structures to connect respective second bond pads with respective second relocated bond pads, and (e) forming RDL interconnection structures to connect first relocated bond pads with second relocated bond pads.

### RELATED APPLICATION

This application claims priority to commonly owned U.S. Provisional Patent Application No. 63/772,815 filed Mar. 17, 2025, the entire contents of which are hereby incorporated by reference for all purposes.

### TECHNICAL FIELD

The present disclosure relates to methods of forming a chiplet device prototype, e.g., for forming a chiplet device having reduced footprint and/or circuitry as compared with a full integrated circuit (IC) device.

### BACKGROUND

In the field of integrated circuit (IC) devices, a chiplet is a specialized semiconductor component designed to perform a specific function within an IC system. Unlike traditional monolithic ICs, in which all components are integrated onto a single silicon die, chiplets break complex systems into smaller, function-specific building blocks, and can be manufactured and assembled independently. Chiplets may be more cost effective and/or more performance oriented than full ICs, as the relevant fabrication facility (e.g., wafer fab) may be optimized for efficiently fabricating the specialized structure of a chiplet. For example, digital blocks having a very small critical dimension may be more efficiently produced in a specialized fabrication process than ICs including digital blocks and analog blocks having larger critical dimensions. In addition, by interconnecting chiplets on a single package, designers can mix and match functionalities to form Heterogenous Integration (HI) modules, allowing for enhanced customization, cost-effectiveness, and improved performance across a wide range of applications.

Chip manufacturers typically have many (e.g., hundreds or thousands) available IC's for potential integration into HI modules, but few are currently designed specifically as chiplets.

There is a need for generating chiplet prototypes starting from existing IC designs.

### SUMMARY

The present disclosure provides methods for relatively quickly and inexpensively implementing a chiplet prototype or early production version of a chiplet when starting from a fully functional device.

An example method takes an existing design and adds a Redistribution Layer (RDL), either in one of our fabs or using an external RDL factory. The re-configured chip has bumps or pads located in the estimated final location and configuration of where the final chiplet design would predict. These pads can then be connected using the final integration assembly method, thereby allowing a fast look-ahead for mechanical, thermal and possibly electrical testing and validation.

In some examples, the process begins with a desired chiplet proposal to break apart or simplify an existing device. But before committing full design resources to isolating the chiplet portion of the original design, a wafer of the existing design may be submitted for RDL processing. This may be done either in an original fab, or at a bumping or panel level assembly facility, for example, depending on the geometry required. After exiting the RDL process, the wafer may be diced and assembled in any of several HI techniques (EMIB, Panel Level, CoWoS, etc.). In some examples, the chiplet circuitry is accessible and functional, the final HI module may be fully tested however in some situations this may not be possible without FIB (Focused Ion Beam) modifications or other interventions. Even a partially functional or mechanical module may be used for reliability testing or early sampling and cycles of learning may be applied before incurring the expense and time of a full re-design to chiplet level.

One aspect provides a method, including forming a first IC device including first IC device circuitry and a plurality of first bond pads, the first IC device circuitry including (a) first function circuitry located in a partial footprint of the first IC device and providing a first functionality, and (b) additional first IC device circuitry located outside the partial footprint of the first IC device, and forming a second IC device including second IC device circuitry and a plurality of second bond pads, the second IC device circuitry including (a) second function circuitry located in a partial footprint of the second IC device and providing a second functionality, and (b) additional second IC device circuitry located outside the partial footprint of the second IC device. The method further includes forming (a) a plurality of first relocated bond pads corresponding with respective ones of the first bond pads and (b) first redistribution layer (RDL) structures on the first IC device and within the partial footprint of the first IC device, the first relocated bond pads having different locations relative to corresponding first bond pads, and the first RDL structures connecting respective first relocated bond pads with corresponding first bond pads. The method further includes forming (a) a plurality of second relocated bond pads corresponding with respective ones of the second bond pads and (b) second RDL structures on the second IC device and within the partial footprint of the second IC device, the second relocated bond pads having different locations relative to corresponding second bond pads, and the second RDL structures connecting respective second relocated bond pads with corresponding second bond pads. The method further includes forming RDL bond pad interconnection structures to connect respective first relocated bond pads formed on the first IC device with respective second relocated bond pads formed on the second IC device, to thereby connect the first function circuitry on the first IC device with the second function circuitry on the second IC device.

In some examples, the method includes forming the first IC device on a first wafer, wherein the footprint of the first IC device comprises a specified partial portion of the first wafer; forming the second IC device on a second wafer, wherein the footprint of the second IC device comprises a specified partial portion of the second wafer; after forming the first relocated bond pads and first RDL structures on the first IC device, dicing the first IC device from the first wafer to provide a diced first IC device; after forming the second relocated bond pads and second RDL structures on the second IC device, dicing the second IC device from the second wafer to provide a diced second IC device; arranging the diced first IC device adjacent the diced second IC device; and forming the RDL bond pad interconnection structures to connect respective first relocated bond pads formed on the first IC device with respective second relocated bond pads formed on the second IC device.

In some examples, the method includes forming the first relocated bond pads and first RDL structures in a first RDL layer on the first IC device, forming the second relocated bond pads and second RDL structures in a first RDL layer on the second IC device, and forming the RDL bond pad interconnection structures in a second RDL layer over (a) the first RDL layer formed on the first IC device and (b) the first RDL layer formed on the second IC device.

In some examples, the first bond pads are located outside the partial footprint of the first IC device, and the second bond pads are located outside the partial footprint of the second IC device.

In some examples, the first function circuitry on the first IC device connected to the second function circuitry on the second IC device by the RDL bond pad interconnection structures defines a prototype of a heterogenous integrated chiplet device.

In some examples, the method includes testing a performance of the heterogenous integrated device, including transmitting signals between the first function circuitry on the first IC device with the second function circuitry on the second IC device via the RDL bond pad interconnection structures.

In some examples, the first IC device comprises a digital block, and the second IC device comprises an analog block.

In some examples, the method includes forming a first chiplet having a footprint corresponding with the partial footprint of the first IC device, and including (a) first chiplet circuitry corresponding with the first function circuitry of the second IC device and (b) first chiplet bond pads corresponding with the first relocated bond pads formed on the first IC device; forming a second chiplet having a footprint corresponding with the partial footprint of the second IC device, and including (a) second chiplet circuitry corresponding with the second function circuitry of the second IC device and (b) second chiplet bond pads corresponding with the second relocated bond pads formed on the second IC device; and forming connections between the first chiplet bond pads of the first chiplet and the second chiplet bond pads of the second chiplet.

Another aspect provides a method, including forming a first wafer including a first IC device including (a) first function circuitry located in a partial footprint of the first IC device and (b) a plurality of first bond pads located outside the partial footprint of the first IC device; and forming a second wafer including a second IC device including (a) second function circuitry located in a partial footprint of the second IC device and (b) a plurality of second bond pads located outside the partial footprint of the second IC device. The method further includes forming (a) a plurality of first relocated bond pads corresponding with respective ones of the first bond pads and (b) first redistribution layer (RDL) structures on the first IC device and within the partial footprint of the first IC device, the first RDL structures connecting respective first relocated bond pads with corresponding first bond pads. The method further includes forming (a) a plurality of second relocated bond pads corresponding with respective ones of the second bond pads and (b) second RDL structures on the second IC device and within the partial footprint of the second IC device, the second RDL structures connecting respective second relocated bond pads with corresponding second bond pads. The method further includes dicing the first IC device from the first wafer to provide a diced first IC device, dicing the second IC device from the second wafer to provide a diced second IC device, arranging the diced first IC device adjacent the diced second IC device, and forming RDL bond pad interconnection structures to connect respective first relocated bond pads formed on the first IC device with respective second relocated bond pads formed on the second IC device, to thereby connect the first function circuitry on the first IC device with the second function circuitry on the second IC device.

In some examples, the method includes forming the first relocated bond pads and first RDL structures in a first RDL layer on the first IC device, forming the second relocated bond pads and second RDL structures in a first RDL layer on the second IC device, and forming the RDL bond pad interconnection structures in a second RDL layer over (a) the first RDL layer formed on the first IC device and (b) the first RDL layer formed on the second IC device.

In some examples, the first function circuitry on the first IC device connected to the second function circuitry on the second IC device by the RDL bond pad interconnection structures defines a prototype of a heterogenous integrated chiplet device.

In some examples, the method includes testing a performance of the heterogenous integrated device, including transmitting signals between the first function circuitry on the first IC device with the second function circuitry on the second IC device via the RDL bond pad interconnection structures.

In some examples, the first IC device comprises a digital block, and the second IC device comprises an analog block.

In some examples, the method includes forming a first chiplet having a footprint corresponding with the partial footprint of the first IC device, and including (a) first chiplet circuitry corresponding with the first function circuitry of the second IC device and (b) first chiplet bond pads corresponding with the first relocated bond pads formed on the first IC device; forming a second chiplet having a footprint corresponding with the partial footprint of the second IC device, and including (a) second chiplet circuitry corresponding with the second function circuitry of the second IC device and (b) second chiplet bond pads corresponding with the second relocated bond pads formed on the second IC device; and forming connections between the first chiplet bond pads of the first chiplet and the second chiplet bond pads of the second chiplet.

Another aspect provides an IC device, comprising a first IC device, a second IC device, and a plurality of RDL bond pad interconnection structures. The first IC device includes first function circuitry located in a partial footprint of the first IC device, additional circuitry located outside the partial footprint of the first IC device, a plurality of first bond pads, and a first IC device redistribution layer (RDL) formed above the first function circuitry, the first IC device RDL including a plurality of first relocated bond pads and first bond pad connection structures formed within the partial footprint of the first IC device, wherein the first relocated bond pads have different locations relative to corresponding first bond pads, and wherein the first bond pad connection structures connect respective first relocated bond pads with corresponding ones of the first bond pads. The second IC device is arranged adjacent the first IC device and includes second function circuitry located in a partial footprint of the second IC device, additional circuitry located outside the partial footprint of the second IC device, a plurality of second bond pads, and a second IC device redistribution layer (RDL) formed above the second function circuitry, the second IC device RDL including a plurality of second relocated bond pads and second bond pad connection structures formed within the partial footprint of the second IC device, wherein the second relocated bond pads have different locations relative to corresponding second bond pads, and wherein the second bond pad connection structures connect respective second relocated bond pads with corresponding ones of the second bond pads;. The plurality of RDL bond pad interconnection structures are formed in an RDL layer above the first IC device RDL layer and the second IC device RDL layer, and connect respective first relocated bond pads formed on the first IC device with respective second relocated bond pads formed on the second IC device, thereby connecting the first function circuitry on the first IC device with the second function circuitry on the second IC device.

In some examples, the first bond pads are located outside the partial footprint of the first IC device, and the second bond pads are located outside the partial footprint of the second IC device.

In some examples, the first bond pads and second bond pads comprise wire bond pads.

In some examples, the first IC device comprises a digital block, and the second IC device comprises an analog block.

### BRIEF DESCRIPTION OF THE DRAWINGS

Example aspects of the present disclosure are described below in conjunction with the figures, in which:

FIGS. 1-4 show an example process for forming a prototype of a heterogeneous integrated chiplet device, for example for testing or otherwise facilitating the construction of a heterogeneous integrated chiplet device; and

FIG. 5 shows an example heterogeneous integrated chiplet device corresponding with the example chiplet device prototype formed according to the example method shown in FIGS. 1-4.

It should be understood that the reference number for any illustrated element that appears in multiple different figures has the same meaning across the multiple figures, and the mention or discussion herein of any illustrated element in the context of any particular figure also applies to each other figure, if any, in which that same illustrated element is shown.

### DETAILED DESCRIPTION

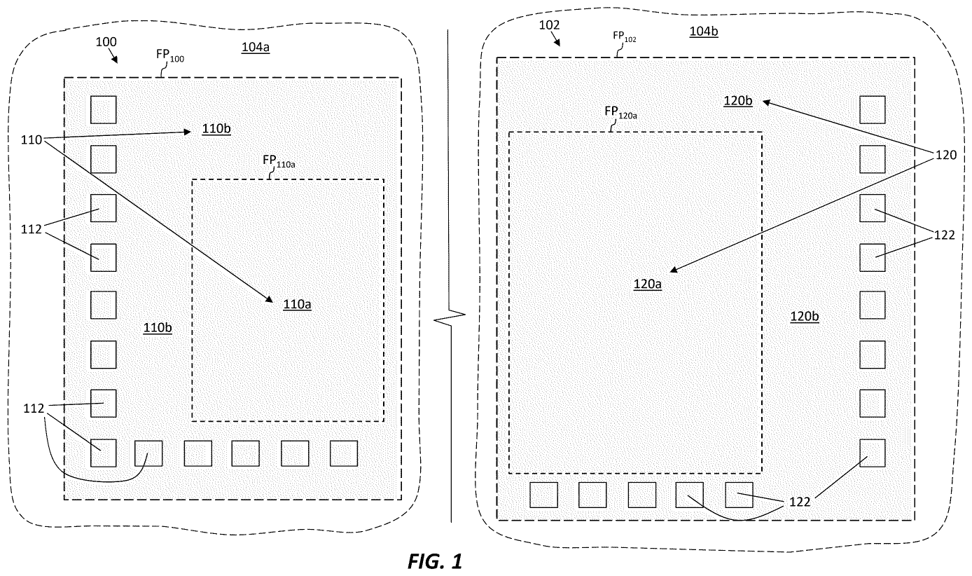

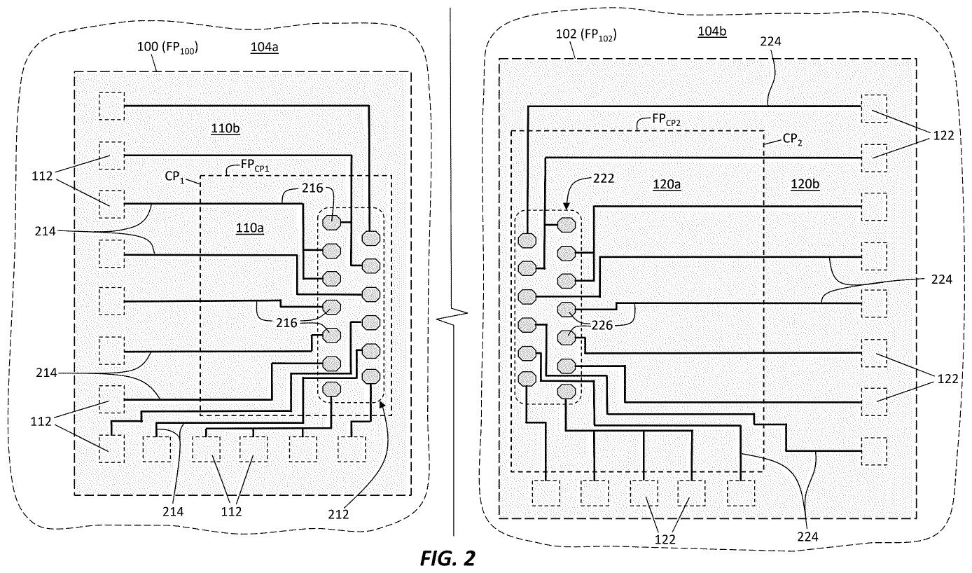

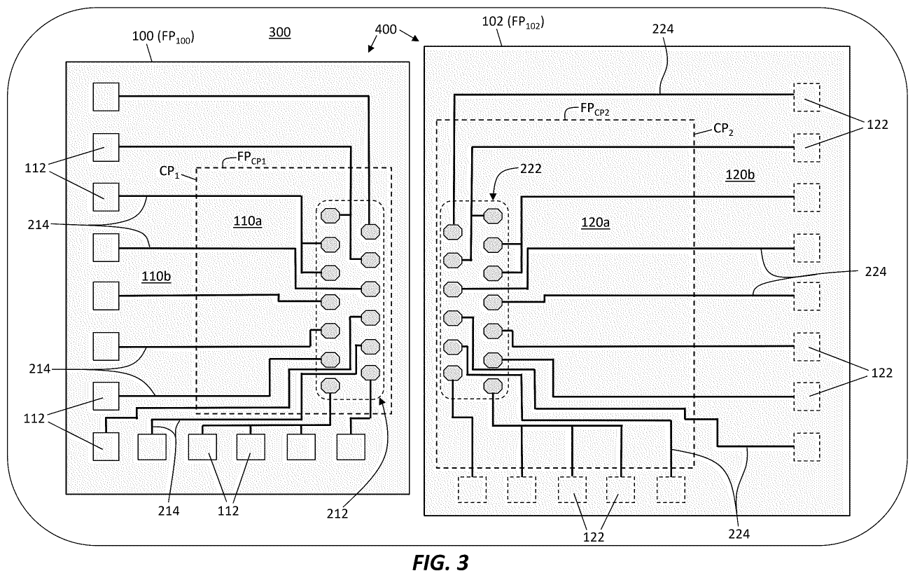

FIGS. 1-4 show an example process for forming a prototype of a multi-chiplet device from an arrangement of multiple IC devices (e.g., chips). FIG. 1 shows a first IC device 100 being formed on a first wafer area 104a and a second IC device 102 being formed on a second wafer area 104b, wherein a “wafer” may refer to a semiconductor wafer, a panel used in panel level packaging (PLP) processing, or other substrate. In some examples, the first wafer area 104a and second wafer area 104b represent different areas of the same wafer. In other examples, the first wafer area 104a represents an area of a first wafer, while the second wafer area 104b represents an areas of the second wafer. Thus, the first IC device 100 and second IC device 102 may be formed on the same wafer or on different wafers. As discussed below with reference to FIGS. 2 and 3, the first IC device 100 and second IC device 102 may be subsequently cut (diced) from the first wafer area 104a and second wafer area 104b, respectively, to define discrete IC devices 100 and 102 that may then be arranged side-by-side and connected to each other.

The first IC device 100 and second IC device 102 may be formed using any suitable fabrication processes. In some examples, the first IC device 100 comprises a digital block, and the second IC device 102 comprises an analog block. In other examples, both the first IC device 100 and second IC device 102 comprise digital blocks. In other examples, both the first IC device 100 and second IC device 102 comprise analog blocks. In one example, the first IC device 100 comprises a memory chip, and the second IC device 102 comprises a microcontroller.

The first IC device 100 has a footprint FP₁₀₀ (corresponding with the footprint of the first IC device 100 after being diced from the first wafer area 104a) and includes first IC device circuitry 110 and a plurality of first bond pads 112 connected to the first IC device circuitry 110. The first IC device circuitry 110 may include (a) first function circuitry 110a providing a first functionality and located in a partial footprint FP₁₁₀ₐ encompassing the first IC device 110, and (b) additional first IC device circuitry 110b providing additional functionality of the first IC device 100 and located outside the partial footprint FP₁₁₀ₐ encompassing the first function circuitry 110a. In an example in which the first IC device 100 comprises a memory chip, the first function circuitry 110a may comprise selected memory circuitry (e.g., SRAM), and the additional first IC device circuitry 110b may comprise, for example, other memory circuitry (e.g., ROM), electrostatic discharge (ESD) circuitry, array organization circuitry, and/or interconnection circuitry to connect the first IC device 100 (e.g., memory chip) to a printed circuitry board (PCB) as a stand-alone device. In some examples, the first function circuitry 110a may be suitable to be formed as a stand-alone chiplet, i.e., distinct from the additional first IC device circuitry 110b.

The first bond pads 112 may comprise any suitable bond pads, for example aluminum pads suitable for wire-bonding to respective posts of an IC package (e.g., a ball grid array or quad flat no-leads (QFN) type package). As shown in FIG. 1, in some examples some or all of the first bond pads 112 may be located outside the partial footprint FP₁₁₀ₐ encompassing the first function circuitry 110a.

The second IC device 102 has a footprint FP₁₀₂ (corresponding with the footprint of the second IC device 102 after being diced from the second wafer area 104b) and includes second IC device circuitry 120 and a plurality of second bond pads 122 connected to the second IC device circuitry 120. The second IC device circuitry 120 may include (a) second function circuitry 120a providing a second functionality and located in a partial footprint FP₁₂₀ₐ of the second IC device 102, and (b) additional second IC device circuitry 120b providing additional functionality of the second IC device 102 and located outside the partial footprint FP_{120b} of the second function circuitry 120b. In an example in which the first IC device 102 comprises a microcontroller, the second function circuitry 120b may comprise logic circuitry, and the additional second IC device circuitry 120b may comprise, for example, internal memory and other circuitry. In some examples, the second function circuitry 120a may be suitable to be formed as a stand-alone chiplet, i.e., distinct from the additional second IC device circuitry 120b.

Like first bond pads 112 discussed above, the second bond pads 122 may comprise any suitable bond pads, for example aluminum pads suitable for wire-bonding to respective posts of an IC package (e.g., a ball grid array or QFN type package). As shown in FIG. 1, in some examples some or all of the second bond pads 122 may be located outside the partial footprint FP_{110b} encompassing the first function circuitry 110b.

FIG. 2 shows further fabrication steps of the first IC device 100 and second IC device 102 being formed on the first wafer area 104a and second wafer area 104b, respectively. In particular, FIG. 2 shows the formation of first relocated bond pads 212 and first redistribution layer (RDL) connection structures 214 on the first IC device 100, and second relocated bond pads 222 and second RDL connection structures 224 on the second IC device 102. In some examples, the first relocated bond pads 212 and first RDL connection structures 214 are formed in a first RDL layer 216 on the first IC device 100, and the second relocated bond pads 222 and second RDL connection structures 224 are formed in a second RDL layer 226 on the second IC device 102. In an example in which the first wafer area 104a and second wafer area 104b comprise areas of the same wafer, the first relocated bond pads 212, first RDL connection structures 214, second relocated bond pads 222, and second RDL connection structures 224 may be formed in the same RDL layer (e.g., first RDL layer) on the wafer. RDL structures as disclosed herein may be formed from aluminum or other suitable metal.

On the first IC device 100, respective first relocated bond pads 212 (13 first relocated bond pads 212 are illustrated) correspond with respective first bond pads 112 (13 first bond pads 112), but having different locations than the first bond pads 112, in particular within the partial footprint FP₁₁₀ₐ encompassing the first function circuitry 110a, and first RDL connection structures 214 connect respective first relocated bond pads 212 with corresponding first bond pads 112. Similarly, on the second IC device 102, respective second relocated bond pads 222 (13 second relocated bond pads 222 are illustrated) correspond with respective second bond pads 122 (13 second bond pads 122), but having different locations than the second bond pads 122, in particular within the partial footprint FP_{110b} encompassing the second function circuitry 110b, and second RDL connection structures 224 connect respective second relocated bond pads 222 with corresponding second bond pads 122.

The first IC device 100 including the first function circuitry 110a connected to first relocated bond pads 212 (by first RDL connection structures 214) may represent a first chiplet prototype CP₁ having a footprint FP_{CP1}=FP₁₂₀ₐ, and the second IC device 102 including the second function circuitry 110b connected to second relocated bond pads 222 (by second RDL connection structures 224) may represent a second chiplet prototype CP₂ having a footprint FP_{CP1}=FP_{120b}.

At some point after forming the first relocated bond pads 212 and first RDL connection structures 214 on the first IC device 100 (e.g., after competing fabrication of the first wafer area 104a), the first IC device 100 the first wafer area 104a may be diced to define as a discrete device. Similarly, after forming the second relocated bond pads 222 and second RDL connection structures 224 on the second IC device 102 (e.g., after competing fabrication of the second wafer area 104b), the second wafer area 104b may be diced to define the second IC device 102 as a discrete device. In examples in which the first wafer area 104a and second wafer area 104b represent different areas of the same wafer, the wafer may be diced to define both the first IC device 100 and the second IC device 102 as discrete devices.

As shown in FIG. 3, the discrete first IC device 100 and discrete second IC device 102 may be arranged laterally adjacent (side-by-side) on a carrier structure 300, e.g., an adhesive tape or other temporary carrier (e.g., a temporary glass carrier), which in some examples may be subsequently removed.

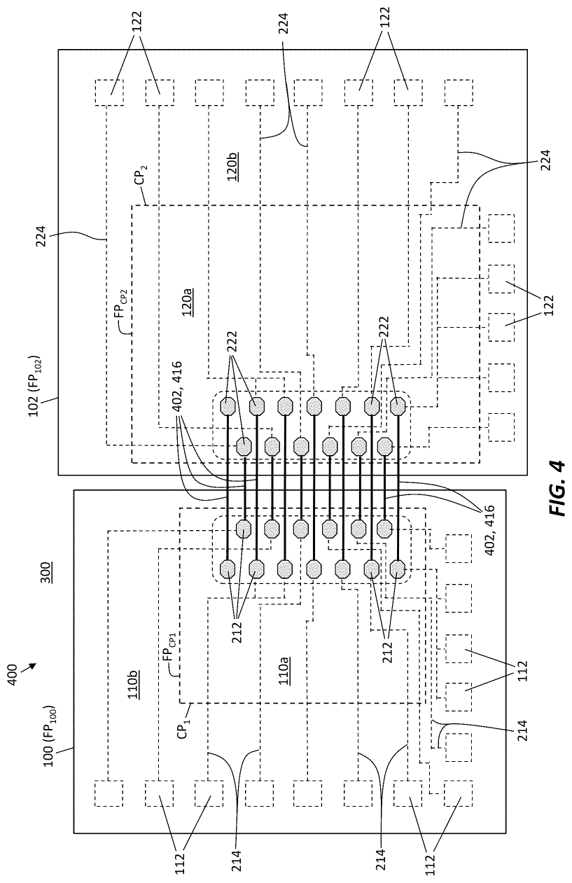

As shown in FIG. 4, RDL bond pad interconnection structures 402 may be formed to connect respective first relocated bond pads 212 on the first IC device 100 with respective second relocated bond pads 222 on the second IC device 102, to thereby connect first function circuitry 110a of the first IC device 100 with respective second function circuitry 110b of the second IC device 102. In some examples, the RDL bond pad interconnection structures 402 may be formed in a second RDL layer 416 over (a) the first RDL layer 216 formed on first IC device 100 (including the first relocated bond pads 212 and first RDL connection structures 214) and (b) the first RDL layer 226 formed on second IC device 102 (including the second relocated bond pads 222 and second RDL connection structures 224).

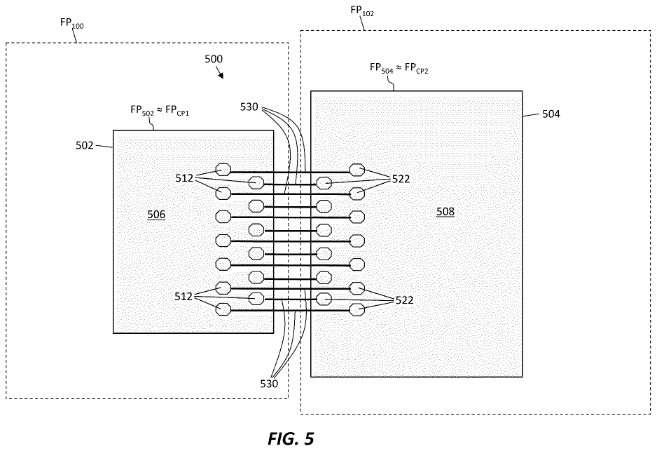

As discussed above, the first function circuitry 110a may be suitable to be formed as a stand-alone chiplet (distinct from the additional first IC device circuitry 110b) and similarly the second function circuitry 110b may be suitable to be formed as a stand-alone chiplet (distinct from the additional second IC device circuitry 120b). Thus, connecting the first function circuitry 110a with the second function circuitry 120a using the RDL bond pad interconnection structures 402 may define a fully or partially functional heterogeneous integrated module 400, i.e., representing a prototype of a heterogeneous integrated chiplet device including the first chiplet prototype CP₁ connected to the chiplet prototype CP₂. This heterogeneous integrated chiplet device prototype 400 may be tested for operability and reliability, using any suitable testing systems and methods. For example, signals may be transmitted between the first function circuitry 110a and second function circuitry 110b (and/or vice versa) via respective RDL bond pad interconnection structures 402 to test the performance of the chiplet device prototype 400. Such testing may confirm or facilitate the construction of a heterogeneous integrated chiplet device including chiplets corresponding with the first chiplet prototype CP₁ and first chiplet prototype CP₁, as discussed below with reference to FIG. 5.

FIG. 5 shows an example heterogeneous integrated chiplet device 500, for example corresponding with the example chiplet device prototype 400 formed as shown in FIGS. 1-4 discussed above. As shown, the heterogeneous integrated chiplet device 500 includes (a) a first chiplet 502 corresponding with the first chiplet prototype CP₁ and having a footprint FP₅₀₂ corresponding with the footprint of the first chiplet prototype footprint FP_{CP1}, and (b) a second chiplet 504 corresponding with the second chiplet prototype CP₂ and having a footprint FP₅₀₄ corresponding with the footprint of the second chiplet prototype footprint FP_{CP2}.

The first chiplet 502 includes (a) first chiplet circuitry 506 corresponding with the first function circuitry 110a of the first IC device 100 discussed above and (b) first chiplet bond pads 512 corresponding with the first relocated bond pads 212 formed on the first IC device 100 discussed above. Similarly, the second chiplet 504 includes (a) second chiplet circuitry 508 corresponding with the second function circuitry 110b of the second IC device 102 discussed above and (b) second chiplet bond pads 522 corresponding with the second relocated bond pads 222 formed on the second IC device 102 discussed above. The first chiplet bond pads 512 are connected to respective second chiplet bond pads 522 by interconnection structures 530 (e.g., formed in RDL), to thereby connect first chiplet circuitry 506 with respective second chiplet circuitry 508.

Example advantages of the disclosed method, as opposed with conventional processes, include providing much faster time to market, allowance of customer demonstration vehicles, advanced reliability or quality testing, and/or faster development of final HI assembly techniques.

Although example embodiments have been described above, other variations and embodiments may be made from this disclosure without departing from the spirit and scope of these embodiments.

1. A method, comprising:
forming a first IC device including first IC device circuitry and a plurality of first bond pads connected to the first IC device circuitry, the first IC device circuitry including first function circuitry located in a partial footprint of the first IC device and providing a first functionality; and
forming a second IC device including second IC device circuitry and a plurality of second bond pads connected to the second IC device circuitry, the second IC device circuitry including second function circuitry located in a partial footprint of the second IC device and providing a second functionality;
forming (a) a plurality of first relocated bond pads corresponding with respective ones of the first bond pads and (b) first redistribution layer (RDL) structures on the first IC device and within the partial footprint of the first IC device, the first relocated bond pads having different locations relative to corresponding first bond pads, and the first RDL structures connecting respective first relocated bond pads with corresponding first bond pads;
forming (a) a plurality of second relocated bond pads corresponding with respective ones of the second bond pads and (b) second RDL structures on the second IC device and within the partial footprint of the second IC device, the second relocated bond pads having different locations relative to corresponding second bond pads, and the second RDL structures connecting respective second relocated bond pads with corresponding second bond pads; and
forming RDL bond pad interconnection structures to connect respective first relocated bond pads formed on the first IC device with respective second relocated bond pads formed on the second IC device, to thereby connect the first function circuitry on the first IC device with the second function circuitry on the second IC device.

2. The method of claim 1, comprising:
forming the first IC device on a first wafer, wherein the footprint of the first IC device comprises a specified partial portion of the first wafer;
forming the second IC device on a second wafer, wherein the footprint of the second IC device comprises a specified partial portion of the second wafer;
after forming the first relocated bond pads and first RDL structures on the first IC device, dicing the first IC device from the first wafer to provide a diced first IC device;
after forming the second relocated bond pads and second RDL structures on the second IC device, dicing the second IC device from the second wafer to provide a diced second IC device;
arranging the diced first IC device adjacent the diced second IC device; and
forming the RDL bond pad interconnection structures to connect respective first relocated bond pads formed on the first IC device with respective second relocated bond pads formed on the second IC device.

3. The method of claim 1, comprising:
forming the first relocated bond pads and first RDL structures in a first RDL layer on the first IC device;
forming the second relocated bond pads and second RDL structures in a first RDL layer on the second IC device; and
forming the RDL bond pad interconnection structures in a second RDL layer over (a) the first RDL layer formed on the first IC device and (b) the first RDL layer formed on the second IC device.

4. The method of claim 1, wherein:
the first IC device circuitry includes additional first IC device circuitry located outside the partial footprint of the first IC device; and
the second IC device includes additional second IC device circuitry located outside the partial footprint of the second IC device.

5. The method of claim 1, wherein:
the first bond pads are located outside the partial footprint of the first IC device; and
the second bond pads are located outside the partial footprint of the second IC device.

6. The method of claim 1, wherein the first function circuitry on the first IC device connected to the second function circuitry on the second IC device by the RDL bond pad interconnection structures defines a prototype of a heterogenous integrated chiplet device.

7. The method of claim 6, comprising testing a performance of the heterogenous integrated device, including transmitting signals between the first function circuitry on the first IC device with the second function circuitry on the second IC device via the RDL bond pad interconnection structures.

8. The method of claim 1, wherein:
the first IC device comprises a digital block; and
the second IC device comprises an analog block.

9. The method of claim 1, comprising:
forming a first chiplet having a footprint corresponding with the partial footprint of the first IC device, and including (a) first chiplet circuitry corresponding with the first function circuitry of the first IC device and (b) first chiplet bond pads corresponding with the first relocated bond pads formed on the first IC device;
forming a second chiplet having a footprint corresponding with the partial footprint of the second IC device, and including (a) second chiplet circuitry corresponding with the second function circuitry of the second IC device and (b) second chiplet bond pads corresponding with the second relocated bond pads formed on the second IC device; and
forming connections between the first chiplet bond pads of the first chiplet and the second chiplet bond pads of the second chiplet.

10. A method, comprising:
forming a first wafer including a first IC device including (a) first function circuitry located in a partial footprint of the first IC device and (b) a plurality of first bond pads located outside the partial footprint of the first IC device;
forming a second wafer including a second IC device including (a) second function circuitry located in a partial footprint of the second IC device and (b) a plurality of second bond pads and located outside the partial footprint of the second IC device;
forming (a) a plurality of first relocated bond pads corresponding with respective ones of the first bond pads and (b) first redistribution layer (RDL) structures on the first IC device and within the partial footprint of the first IC device, the first RDL structures connecting respective first relocated bond pads with corresponding first bond pads;
forming (a) a plurality of second relocated bond pads corresponding with respective ones of the second bond pads and (b) second RDL structures on the second IC device and within the partial footprint of the second IC device, the second RDL structures connecting respective second relocated bond pads with corresponding second bond pads;
dicing the first IC device from the first wafer to provide a diced first IC device;
dicing the second IC device from the second wafer to provide a diced second IC device;
arranging the diced first IC device adjacent the diced second IC device; and
forming RDL bond pad interconnection structures to connect respective first relocated bond pads formed on the first IC device with respective second relocated bond pads formed on the second IC device, to thereby connect the first function circuitry on the first IC device with the second function circuitry on the second IC device.

11. The method of claim 10, comprising:
forming the first relocated bond pads and first RDL structures in a first RDL layer on the first IC device;
forming the second relocated bond pads and second RDL structures in a first RDL layer on the second IC device; and
forming the RDL bond pad interconnection structures in a second RDL layer over (a) the first RDL layer formed on the first IC device and (b) the first RDL layer formed on the second IC device.

12. The method of claim 10, wherein the first function circuitry on the first IC device connected to the second function circuitry on the second IC device by the RDL bond pad interconnection structures defines a prototype of a heterogenous integrated chiplet device.

13. The method of claim 12, comprising testing a performance of the heterogenous integrated device, including transmitting signals between the first function circuitry on the first IC device with the second function circuitry on the second IC device via the RDL bond pad interconnection structures.

14. The method of claim 10, wherein:
the first IC device comprises a digital block; and
the second IC device comprises an analog block.

15. The method of claim 10, comprising:
forming a first chiplet having a footprint corresponding with the partial footprint of the first IC device, and including (a) first chiplet circuitry corresponding with the first function circuitry of the second IC device and (b) first chiplet bond pads corresponding with the first relocated bond pads formed on the first IC device;
forming a second chiplet having a footprint corresponding with the partial footprint of the second IC device, and including (a) second chiplet circuitry corresponding with the second function circuitry of the second IC device and (b) second chiplet bond pads corresponding with the second relocated bond pads formed on the second IC device; and
forming connections between the first chiplet bond pads of the first chiplet and the second chiplet bond pads of the second chiplet.

16. An integrated circuit (IC) device, comprising:
a first IC device including:
first function circuitry located in a partial footprint of the first IC device;
a plurality of first bond pads; and
a first IC device redistribution layer (RDL) formed above the first function circuitry, the first IC device RDL including a plurality of first relocated bond pads and first bond pad connection structures formed within the partial footprint of the first IC device, wherein the first relocated bond pads have different locations relative to corresponding first bond pads, and wherein the first bond pad connection structures connect respective first relocated bond pads with corresponding ones of the first bond pads;
a second IC device arranged adjacent the first IC device and including:
second function circuitry located in a partial footprint of the second IC device;
a plurality of second bond pads; and
a second IC device redistribution layer (RDL) formed above the second function circuitry, the second IC device RDL including a plurality of second relocated bond pads and second bond pad connection structures formed within the partial footprint of the second IC device, wherein the second relocated bond pads have different locations relative to corresponding second bond pads, and wherein the second bond pad connection structures connect respective second relocated bond pads with corresponding ones of the second bond pads;
a plurality of RDL bond pad interconnection structures formed in an RDL layer above the first IC device RDL layer and the second IC device RDL layer, the plurality of RDL bond pad interconnection structures connect respective first relocated bond pads formed on the first IC device with respective second relocated bond pads formed on the second IC device, thereby connecting the first function circuitry on the first IC device with the second function circuitry on the second IC device.

17. The IC device of claim 16, wherein:
the first bond pads are located outside the partial footprint of the first IC device; and
the second bond pads are located outside the partial footprint of the second IC device.

18. The IC device of claim 16, wherein the first bond pads and second bond pads comprise wire bond pads.

19. The IC device of claim 16, wherein:
the first IC device comprises a digital block; and
the second IC device comprises an analog block.

20. The IC device of claim 16, wherein:
the first IC device includes additional circuitry located outside the partial footprint of the first IC device; and
the second IC device includes additional circuitry located outside the partial footprint of the second IC device.
